(19) United States
(12) Patent Application Publication
(10) Pub. No.: US 2024/0147812 A1
(43) Pub. Date: May 2, 2024

(54) ORGANIC LIGHT EMITTING DIODE DISPLAY PANEL AND METHOD OF MANUFACTURING THE SAME, AND DISPLAY TERMINAL

(71) Applicant: Shenzhen China Star Optoelectronics Semiconductor Display Technology Co., Ltd., Shenzhen (CN)

(72) Inventors: Huan DUAN, Shenzhen (CN); Yi ZHUO, Shenzhen (CN); Fangmei LIU, Shenzhen (CN); Zhiwei SONG, Shenzhen (CN); Gaobo LIN, Shenzhen (CN); Kai HU, Shenzhen (CN)

(21) Appl. No.: 18/474,284

(22) Filed: Sep. 26, 2023

(30) Foreign Application Priority Data
Nov. 2, 2022 (CN) 202211363356.2

(51) Int. Cl. H10K 59/80; H10K 59/12; H10K 59/122; H10K 71/20; H10K 71/60

(52) U.S. Cl. CPC H10K 59/80521; H10K 59/1201; H10K 59/122; H10K 59/8792; H10K 71/231; H10K 71/60

(57) ABSTRACT

The present application provides an organic light emitting diode (OLED) display panel and a method of manufacturing the same, and a display terminal. The OLED display panel includes an array substrate, a protective layer and a cathode. The array substrate includes a first auxiliary electrode, a second auxiliary electrode, and a third auxiliary electrode. The third auxiliary electrode is connected to the first auxiliary electrode and the second auxiliary electrode. The protective layer is provided with an undercut opening exposing a portion of the third auxiliary electrode. The cathode extends into the undercut opening and is connected to the third auxiliary electrode.

### TECHNICAL FIELD

The present application relates to the field of display technologies, and especially relates to an organic light emitting diode (OLED) display panel and a method of manufacturing the same, and a display terminal.

### BACKGROUND

Among flat panel display technologies, organic light emitting diode (OLED) display devices have many advantages such as lightweight and thinness, active light emission, fast response speed, large viewing angle, wide color gamut, high brightness and low power consumption.

For existing OLED display panels in prior art, in order to increase transmittances of the OLED display panels of top emission, the thickness of a metal cathode is thin, and thus a square resistance of the metal cathode is large, and a voltage drop (IR-drop) is serious. As a result, the OLED display panels have obvious uneven brightness phenomenon, which seriously affects display effects of the OLED display devices.

### SUMMARY

An object of the present application is to provide an organic light emitting diode (OLED) display panel and a method of manufacturing the same, and a display terminal, so as to solve a technical problem that the OLED display panel has a poor display effect caused by a large impedance of a cathode of which the thickness is thin.

In order to achieve the object mentioned above, the present application provides an organic light emitting diode (OLED) display panel. The OLED display panel includes an array substrate, a protective layer, an anode, a light emitting functional layer, and a cathode. The array substrate includes a first auxiliary electrode, a second auxiliary electrode, a third auxiliary electrode, and interlayer insulating layers. The interlayer insulating layers are disposed between the first auxiliary electrode and the second auxiliary electrode, and between the second auxiliary electrode and the third auxiliary electrode. The second auxiliary electrode is disposed on the first auxiliary electrode, and the third auxiliary electrode is disposed on the second auxiliary electrode. The third auxiliary electrode is connected to the first auxiliary electrode and the second auxiliary electrode. The protective layer is disposed on the third auxiliary electrode, and is provided with an undercut opening. The undercut opening is configured to expose a portion of the third auxiliary electrode. The anode is disposed on the protective layer. The light emitting functional layer is disposed on the anode. The cathode is disposed on the light emitting functional layer, and the cathode extends into the undercut opening and is connected to the third auxiliary electrode.

Further, the third auxiliary electrode is connected to the first auxiliary electrode by at least one first conductive hole. The third auxiliary electrode is connected to the second auxiliary electrode by at least one second conductive hole.

Further, the third auxiliary electrode is connected to the first auxiliary electrode by two first conductive holes. One of the two first conductive holes is connected to one side of the first auxiliary electrode, and another one of the two first conductive holes is connected to another side of the first auxiliary electrode. The second auxiliary electrode is disposed between the two first conductive holes.

Further, the third auxiliary electrode is connected to the second auxiliary electrode by two second conductive holes.

Further, the array substrate further includes a light shielding layer, a gate, and a source-drain electrode. The light shielding layer is disposed in a same layer as the first auxiliary electrode. The gate is disposed in a same layer as the second auxiliary electrode. The source-drain electrode is disposed in a same layer as the third auxiliary electrode.

Further, the OLED display panel further includes a substrate layer, a buffer layer, an active layer, a first gate insulating layer, a second gate insulating layer, and a dielectric layer. The light shielding layer and the first auxiliary electrode are disposed on the substrate layer. The buffer layer is disposed on the substrate layer and covers the light shielding layer and the first auxiliary electrode. The active layer is disposed on the buffer layer. An orthographic projection of the active layer on the substrate layer falls within an orthographic projection of the light shielding layer on the substrate layer. The first gate insulating layer is correspondingly disposed on the active layer. The second gate insulating layer is correspondingly disposed on the buffer layer. The gate is correspondingly disposed on the first gate insulating layer, and the second auxiliary electrode is correspondingly disposed on the second gate insulating layer. An orthographic projection of the second auxiliary electrode on the substrate layer at least partially overlaps with an orthographic projection of the first auxiliary electrode on the substrate layer. The dielectric layer covers the gate and the second auxiliary electrode, and extends onto the buffer layer. The source-drain electrode is disposed on the dielectric layer and is connected to the active layer. The third auxiliary electrode is disposed on the dielectric layer, and is connected to the first auxiliary electrode and the second auxiliary electrode. An orthographic projection of the third auxiliary electrode on the substrate layer at least partially overlaps with an orthographic projection of the first auxiliary electrode on the substrate layer. The interlayer insulating layers includes the buffer layer, the dielectric layer, and the protective layer.

Further, the protective layer includes a passivation layer and a planarization layer. The passivation layer is disposed on the third auxiliary electrode, and is provided with a first through hole. The planarization layer is disposed on the passivation layer, and is provided with a second through hole. The second through hole is communicated with the first through hole. An orthographic projection of the second through hole on the array substrate completely falls within an orthographic projection of the first through hole on the array substrate, so that the undercut opening is defined between the planarization layer and the passivation layer.

Further, the OLED display panel further includes a pixel defining layer. The pixel defining layer is disposed on the protective layer, and is provided with a third through hole and a pixel opening. The third through hole is communicated with the second through hole, and the pixel opening is configured to expose the anode. The light emitting functional layer is disposed on the anode and the pixel defining layer. The cathode is disposed on the light emitting functional layer and extends into the third through hole and the undercut opening, and the cathode is connected to the third auxiliary electrode.

In order to achieve the object mentioned above, the present application further provides a method of manufacturing an organic light emitting diode (OLED) display panel. The method includes following steps: forming an array substrate; forming a protective layer disposed on a third auxiliary electrode and extending to the array substrate; performing a hole-digging treatment on the protective layer, so that the protective layer is provided with an undercut opening exposing a portion of the third auxiliary electrode; forming an anode disposed on the protective layer; forming a light emitting functional layer disposed on the anode; and forming a cathode disposed on the light emitting functional layer, the cathode extends into the undercut opening and is connected to the third auxiliary electrode. The forming of the array substrate includes following steps: forming a first metal layer; patterning the first metal layer to form a first auxiliary electrode; forming a second metal layer on the first metal layer; patterning the second metal layer to form a second auxiliary electrode; forming a third metal layer on the second metal layer; patterning the third metal layer to form the third auxiliary electrode. Interlayer insulating layers are disposed between the first auxiliary electrode and the second auxiliary electrode, and between the second auxiliary electrode and the third auxiliary electrode. The third auxiliary electrode is connected to the first auxiliary electrode and the second auxiliary electrode.

Further, the step of forming the protective layer includes: forming a passivation layer on the third auxiliary electrode; and forming a planarization layer disposed on the passivation layer. The step of performing the hole-digging treatment on the protective layer includes: performing the hole-digging treatment on the planarization layer and the passivation layer, so that the passivation layer is provided with a first through hole, and the planarization layer is provided with a second through hole communicate with the first through hole; and
etching the passivation layer by a wet etching process, so that an orthographic projection of the second through hole on the array substrate falls into an orthographic projection of the first through hole on the array substrate. The undercut opening is defined between the planarization layer and the passivation layer.

Further, in the step of patterning the first metal layer to form a first auxiliary electrode, the first metal layer is patterned to form a light shielding layer disposed in a same layer as the first auxiliary electrode. In the step of patterning the second metal layer to form a second auxiliary electrode, the second metal layer is patterned to form a gate disposed in a same layer as the second auxiliary electrode. In the step of patterning the third metal layer to form a third auxiliary electrode, the third metal layer is patterned to form a source-drain electrode disposed in a same layer as the third auxiliary electrode.

In order to achieve the object mentioned above, the present application further provides a display terminal including a terminal body and any one of embodiments of the OLED display panel mentioned above. The terminal body is connected to the OLED display panel.

In terms of beneficial effects of the present application, the OLED display panel and the method of manufacturing the same, and the display terminal are provided. The array substrate includes the first auxiliary electrode, the second auxiliary electrode, and the third auxiliary electrode that are insulated from each other. The third auxiliary electrode is connected to the first auxiliary electrode and the second auxiliary electrode to form a cathode overlapping structure. The protective layer is provided with the undercut opening configured to expose a portion of the third auxiliary electrode. The cathode is connected to the cathode overlapping structure to define a cathode overlapping region, so that an impedance of the cathode is reduced, thereby reducing a voltage drop (IR Drop). Therefore, display brightness of each region of the OLED display panel is consistent, thereby further improving display uniformity of the OLED display panel.

### BRIEF DESCRIPTION OF THE DRAWINGS

The technical solutions and other beneficial effects of the present application are obvious by detailed description of specific implementations of the present application in combination with accompanying drawings.

FIG. 1 is a structural schematic diagram of an organic light emitting diode (OLED) display panel provided by an embodiment 1 of the present application.

FIG. 2 is a structural schematic diagram of a light emitting functional layer provided by the embodiment 1 of the present application.

FIG. 3 is a flow chart of a method of manufacturing the OLED display panel provided by the embodiment 1 of the present application.

FIG. 4 is a flow chart showing steps of forming an array substrate provided by the embodiment 1 of the present application.

FIG. 5 is a structural schematic diagram of the array substrate provided by the embodiment 1 of the present application.

FIG. 6 is structural schematic diagram of forming a protective layer provided by the embodiment 1 of the present application.

FIG. 7 is a flow chart showing steps of forming the protective layer provided by the embodiment 1 of the present application.

FIG. 8 is a structural schematic diagram of forming an undercut opening provided by the embodiment 1 of the present application.

FIG. 9 is a flow chart showing steps of forming the undercut opening provided by the embodiment 1 of the present application.

FIG. 10 is a structural schematic diagram of forming a pixel defining layer provided by the embodiment 1 of the present application.

FIG. 11 is a structural schematic diagram of an organic light emitting diode (OLED) display panel provided by an embodiment 2 of the present application.

Elements in the accompanying drawings are designed by reference numerals listed below.
1, array substrate; 2, protective layer; 3, anode; 4, light emitting functional layer; 5, pixel defining layer; 6, cathode; 11, substrate layer; 12, first metal layer; 13, buffer layer; 14, active layer; 15, gate insulating layer; 16, second metal layer; 17, dielectric layer; 18, third metal layer; 121, first auxiliary electrode; 122, light shielding layer; 141, channel region; 142, source contact region; 143, drain contact region; 144, first storage capacitor electrode; 151, first gate insulating layer; 152, second gate insulating layer; 161, gate; 162, second auxiliary electrode; 181, source electrode; 182, drain electrode; 183, third auxiliary electrode; 184, second storage capacitor electrode;
21, passivation layer; 22, planarization layer; 41, hole injection layer; 42, hole transporting layer; 43, light emitting layer; 44, electron transporting layer; 45, electron injection layer; 71, first conductive hole; 72, second conductive hole; 73, third conductive hole; 74, fourth conductive hole; 91, first through hole; 92, second through hole; 93, third through hole; 94, fourth through hole; 95, fifth through hole; 96, pixel opening; 10, undercut opening.

### DETAILED DESCRIPTION OF THE EMBODIMENT

The technical solutions in the embodiments of the present application are clearly and completely described below in conjunction with the drawings in the embodiments of the present application. Obviously, the embodiments described are only a part of the embodiments of the present application, rather than all the embodiments. Based on the embodiments in the present application, all other embodiments obtained by those skilled in the art without creative works should be deemed as falling within the claims of the present application.

In the present disclosure, a structure in which a first feature is “on” or “beneath” a second feature may include an embodiment in which the first feature directly contacts the second feature, and may also include an embodiment in which an additional feature is formed between the first feature and the second feature so that the first feature does not directly contact the second feature, unless otherwise specified. Furthermore, a first feature “on,” “above,” or “on top of” a second feature may include an embodiment in which the first feature is right “on,” “above,” or “on top of” the second feature, and may also include an embodiment in which the first feature is not right “on,” “above,” or “on top of” the second feature, or just means that the first feature has a sea level elevation larger than the sea level elevation of the second feature. While first feature “beneath,” “below,” or “on bottom of” a second feature may include an embodiment in which the first feature is right “beneath,” “below,” or “on bottom of” the second feature, and may also include an embodiment in which the first feature is not right “beneath,” “below,” or “on bottom of” the second feature, or just means that the first feature has a sea level elevation smaller than the sea level elevation of the second feature.

### Embodiment 1

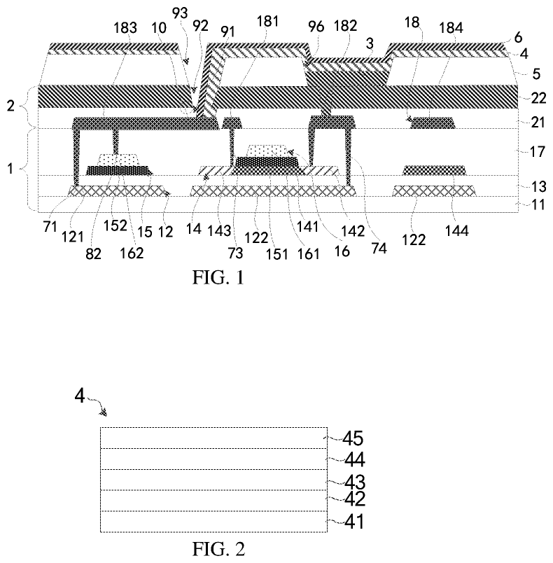

As shown in FIG. 1, this embodiment provides an organic light emitting diode (OLED) display panel. The OLED display panel includes an array substrate 1, a protective layer 2, an anode 3, a pixel defining layer 5, a light emitting functional layer 4, and a cathode 6.

The array substrate 1 includes a substrate layer 11, a first metal layer 12, a buffer layer 13, an active layer 14, a gate insulating layer 15, a second metal layer 16, a dielectric layer 17, and a third metal layer 18.

The substrate layer 11 may be a flexible substrate. A material of the substrate layer 11 can be polyimide (PI) or polydimethylsiloxane (PDMS), which is not specifically limited here.

The first metal layer 12 is disposed on an upper surface of the substrate layer 11. The first metal layer 12 includes a light shielding layer 122 and a first auxiliary electrode 121 which are formed by patterning processes. The light-shielding layer 122 and the first auxiliary electrode 121 are disposed in a same layer.

The buffer layer 13 covers the first auxiliary electrode 121 and the light shielding layer 122, and extends to the upper surface of the substrate layer 11.

A semiconductor layer includes an active layer 14 and a first storage capacitor electrode 144. The active layer 14 and the first storage capacitor electrode 144 are both disposed on an upper surface of the buffer layer 13. An orthographic projection of the active layer 14 on the substrate layer 11 falls within an orthographic projection of the light shielding layer 122 on the substrate layer 11. The active layer 14 includes a channel region 141, a source contact region 142 and a drain contact region 143 disposed at two sides of the channel region 141. The active layer 14 is spaced apart from the first storage capacitor electrode 144. The light shielding layer 122 is disposed correspondingly to the first storage capacitor electrode 144 to form a first storage capacitor.

In this embodiment, the source contact region 142 and the drain contact region 143 of the active layer 14, and the first storage capacitor electrode 144 are all ion-doped regions, and have conductor characteristics. The channel region 141 is a non-doped region, and has semiconductor characteristics. In an embodiment, a material of the active layer 14 may be oxide semiconductor material, such as indium zinc oxide (IZO), gallium indium oxide (IGO), indium gallium zinc oxide (IGZO), indium gallium tin oxide (IGTO), and indium gallium zinc tin oxide (IGZTO). In another embodiment, a material of the active layer 14 may also be amorphous silicon, monocrystalline silicon, low temperature polysilicon, etc.

The gate insulating layer 15 includes a first gate insulating layer 151 and a second gate insulating layer 152 disposed in different layers. The first gate insulating layer 151 is correspondingly disposed on an upper surface of the active layer 14. The second gate insulating layer 152 is correspondingly disposed on the upper surface of the buffer layer 13.

The second metal layer 16 is disposed on an upper surface of the gate insulating layer 15. The second metal layer 16 includes a gate 161 and a second auxiliary electrode 162 which are formed by patterning processes. The gate 161 and the second auxiliary electrode 162 are formed in a same process step. That is, the gate 161 and the second auxiliary electrode 162 are disposed in a same layer. Specifically, the gate 161 is correspondingly disposed on an upper surface of the first gate insulating layer 151, and the second auxiliary electrode 162 is correspondingly disposed on an upper surface of the second gate insulating layer 152. An orthographic projection of the second auxiliary electrode 162 on the substrate layer 11 at least partially overlaps with an orthographic projection of the first auxiliary electrode 121 on the substrate layer 11.

The dielectric layer 17 is disposed on the second metal layer 16. The dielectric layer 17 covers the gate 161 and the second auxiliary electrode 162, and extends to the upper surface of the buffer layer 13.

The third metal layer 18 is disposed on an upper surface of the dielectric layer 17. The third metal layer 18 includes a source-drain electrode, a third auxiliary electrode 183, and a second storage capacitor electrode 184 which are formed by patterning process. The source-drain electrode, the third auxiliary electrode 183, and the second storage capacitor electrode 184 are disposed in a same layer. Specifically, the source-drain electrode is disposed on the dielectric layer 17, and is connected to the active layer 14. The third auxiliary electrode 183 is disposed on the dielectric layer 17, and is connected to the first auxiliary electrode 121 and the second auxiliary electrode 162. An orthographic projection of the third auxiliary electrode 183 on the substrate layer 11 at least partially overlaps with an orthographic projection of the first auxiliary electrode 121 on the substrate layer 11. In this embodiment, the source-drain electrode includes a source electrode 181 and a drain electrode 182. The source electrode 181 is connected to one side of the active layer 14, and the drain electrode 182 is connected to another side of the active layer 14. The source electrode 181 is connected to the active layer 14 by one third conductive hole 73. The drain electrode 182 is connected to the active layer 14 by another third conductive hole 73, and is connected to the light shielding layer 122 by a fourth conductive hole 74, so that an electrical performance of a transistor is improved, and a current of channel is more stable. The light shielding layer 122 is disposed correspondingly to the first storage capacitor electrode 144. The first storage capacitor electrode 144 is disposed correspondingly to the second storage capacitor electrode 184 to form a second storage capacitor.

In this embodiment, materials of the first metal layer 12, the second metal layer 16, and the third metal layer 18 may be individually selected from one or more material including metals, alloys and metal nitrides. For example, metals such as aluminum (Al), silver (Ag), tungsten (W), copper (Cu), nickel (Ni), chromium (Cr), molybdenum (Mo), titanium (Ti), platinum (Pt), tantalum (Ta), and neodymium (Nd), or alloys or nitrides of the aforesaid metals, which may be used alone or in combination.

The protective layer 2 is disposed on the third metal layer 18. The protective layer 2 covers the source-drain electrodes 182 and the third auxiliary electrode 183, and extends to an upper surface of the dielectric layer 17. Specifically, the protective layer 2 includes a passivation layer 21 and a planarization layer 22. The passivation layer 21 is disposed on the third auxiliary electrode 183. The passivation layer 21 is provided with a first through hole 91. The planarization layer 22 is disposed on the passivation layer 21. The planarization layer 22 is provided with a second through hole 92. The second through hole 92 is communicated with the first through hole 91. A portion of the planarization layer 22 extends into the first through hole 91, so that an undercut opening 10 is defined between the planarization layer 22 and the passivation layer 21. The undercut opening 10 is configured to expose a portion of the third auxiliary electrode 183. In this embodiment, the diameter of a bottom portion of the second through hole 92 is less than the diameter of a top portion of the first through hole 91, such an arrangement ensure that an orthographic projection of the second through hole 92 on the array substrate 1 completely falls into an orthographic projection of the first through hole 91 on the array substrate 1, so that the undercut opening 10 is defined between the planarization layer 22 and the passivation layer 21. Preferably, the diameter of an orthographic projection of the second through hole 92 on the substrate layer 11 is less than the diameter of an orthographic projection of the first through hole 91 on the substrate layer 11, such an arrangement further ensure that at least a portion of the planarization layer 22 can extend into the first through hole 91, so that the undercut opening 10 is defined between the planarization layer 22 and the passivation layer 21.

In this embodiment, materials of the buffer layer 13, the gate insulating layer 15, the dielectric layer 17, and the protective layer 2 may be selected from one or more materials including silicon nitride (SiNx), silicon oxide (SiOx), and silicon oxynitride (SiOxNy). It should be noted that the buffer layer 13, the dielectric layer 17, and the protective layer 2 in combination constitute interlayer insulating layers between the first auxiliary electrode 121 and the second auxiliary electrode 162, and between the second auxiliary electrode 162 and the third auxiliary electrode 183.

The anode 3 is disposed on the protective layer 2, and is connected to the source-drain electrode. A material of the anode 3 may be a transparent conductive metal oxide, such as indium tin oxide (ITO).

The pixel defining layer 5 is disposed on the protective layer 2. Specifically, the pixel defining layer 5 is provided with a third through hole 93 and a pixel opening 96. The third through hole 93 is communicated with the second through hole 92. The pixel opening 96 is configured to expose the anode 3.

The light emitting functional layer 4 is disposed on the anode 3 and the pixel defining layer 5, and is disconnected at the undercut opening 10. That is, a portion of the light emitting functional layer 4 may be connected to the third auxiliary electrode 183 disposed at the undercut opening 10, and other portions of the light emitting functional layer 4 may not be connected to the third auxiliary electrode 183 disposed at the undercut opening 10. That is, the undercut opening 10 may disconnect some of the film layers thereon. In this embodiment, as shown in FIG. 2, the light emitting functional layer 4 sequentially includes a hole injection layer 41, a hole transporting layer 42, a light emitting layer 43, an electron transporting layer 44, and an electron injection layer 45 from bottom to top. A structure of the light emitting functional layer 4 may refer to a structure of an existing organic light emitting device, which is not repeated here.

As shown in FIG. 1, the cathode 6 is disposed on the light emitting functional layer 4. The cathode 6 extends into the undercut opening 10, and is connected to the third auxiliary electrode 183. A pattern of the cathode 6 is the same as that of the light emitting functional layer 4. A materials of the cathode 6 may be metal or alloy, such as silver or magnesium-silver alloy. It can be understood that the cathode 6 has a light-transmitting property, so that lights emitted by the light emitting layer 43 can pass through the cathode 6 and be emitted. That is, the OLED display panel provided in this embodiment is a top-emission organic light emitting diode (OLED) display panel. Exemplarily, a light transmittance of the cathode 6 is greater than 30%, such as 30%, 40%, 50%, 60%, 70%, 80%, 90%, 95%, or 99%.

In this embodiment, the third auxiliary electrode 183 is connected to the first auxiliary electrode 121 by at least one first conductive hole 71. The third auxiliary electrode 183 is connected to the second auxiliary electrode 162 by at least one second conductive hole 72. Each first conductive hole 71 goes through the dielectric layer 17 and the buffer layer 13, and is connected to the first auxiliary electrode 121. Each second conductive hole 72 goes through the dielectric layer 17, and is connected to the second auxiliary electrode 162.

The third auxiliary electrode 183 is connected to the first auxiliary electrode 121 by the first conductive hole 71. The third auxiliary electrode 183 is connected to the second auxiliary electrode 162 by the second conductive hole 72. With such an arrangement, the third auxiliary electrode 183 is connected to the second auxiliary electrode 162 and the first auxiliary electrode 121 to form a cathode overlapping structure. The cathode overlapping structure can reduce an impedance of the cathode 6 thereby improving a display uniformity of the OLED display panel.

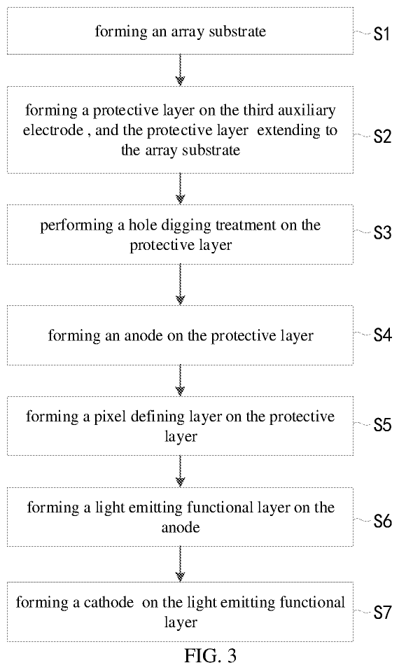

As shown in FIG. 3, this embodiment further provides a method of manufacturing an organic light emitting diode (OLED) display panel, the method includes following steps S1)-S7).
Step S1): forming an array substrate 1. Steps of forming the array substrate 1 include, forming a first metal layer 12; patterning the first metal layer 12 to form a first auxiliary electrode 121; forming a second metal layer 16 on the first metal layer 12; patterning the second metal layer 16 to form a second auxiliary electrode 162; forming a third metal layer 18 on the second metal layer 16; and patterning the third metal layer 18 to form a third auxiliary electrode 183. Interlayer insulating layers are disposed between the first auxiliary electrode 121 and the second auxiliary electrode 162, and between the second auxiliary electrode 162 and the third auxiliary electrode 183. The third auxiliary electrode 183 is connected to the first auxiliary electrode 121 and the second auxiliary electrode 162.

In the step of forming the first auxiliary electrode 121, the first metal layer 12 is patterned to form a light shielding layer 122. The light shielding layer 122 and the first auxiliary electrode 121 are disposed in a same layer. In the step of forming the second auxiliary electrode 162, the second metal layer 16 is patterned to form a gate 161. The gate 161 and the second auxiliary electrode 162 are disposed in a same layer. In the step of forming the third auxiliary electrode 183, the third metal layer 18 is patterned to form the source-drain electrode, and the source-drain electrode and the third auxiliary electrode 183 are disposed in a same layer.

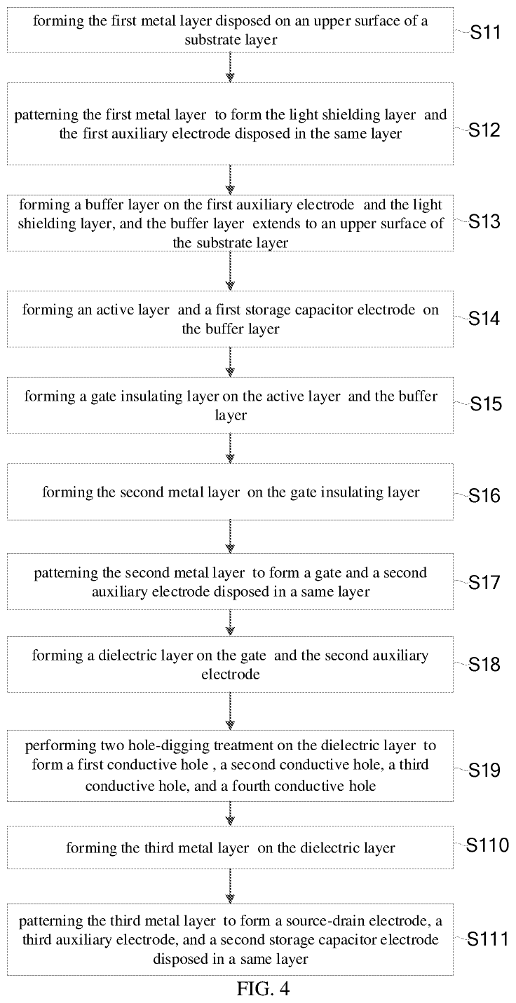

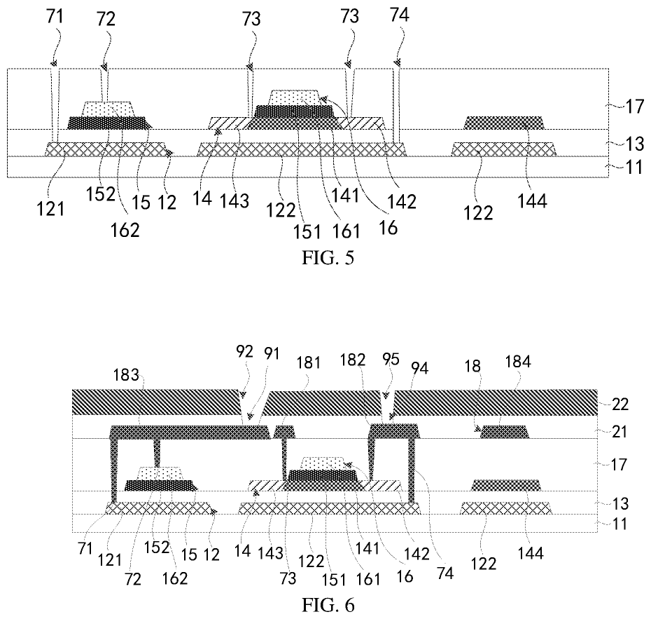

Specifically, as shown in FIG. 4, the steps of forming the array substrate 1 include step S11) to step S111).
Step S11): forming the first metal layer 12 disposed on an upper surface of a substrate layer 11, referring to FIG. 5. Specifically, a metal material is deposited on the upper surface of the substrate layer 11 to form the first metal layer 12. the metal material may be selected from the group including aluminum (Al), silver (Ag), tungsten (W), copper (Cu), nickel (Ni), chromium (Cr), molybdenum (Mo), titanium (Ti), platinum (Pt), tantalum (Ta), neodymium (Nd), etc., or alloys or nitrides of the aforesaid metal material. Theses material may be used alone or in combination.
Step S12): patterning the first metal layer 12 to form the light shielding layer 122 and the first auxiliary electrode 121 disposed in the same layer, as shown in FIG. 5.
Step S13): forming a buffer layer 13 on the first auxiliary electrode 121 and the light shielding layer 122, and the buffer layer 13 extends to an upper surface of the substrate layer 11, referring to FIG. 5. Specifically, an inorganic material is deposited on upper surfaces of the first auxiliary electrode 121 and the light shielding layer 122 to form the buffer layer 13. The buffer layer 13 covers the first auxiliary electrode 121 and the light shielding layer 122, and extends to the upper surface of the substrate layer 11. The inorganic material may be selected from one or more material including silicon nitride (SiNx), silicon oxide (SiOx), and silicon oxynitride (SiOxNy).
Step S14): forming an active layer 14 and a first storage capacitor electrode 144 on the buffer layer 13, referring to FIG. 5. Specifically, the active layer 14 and the first storage capacitor electrode 144 disposed in a same layer are formed on an upper surface of the buffer layer 13. An orthographic projection of the active layer 14 on the substrate layer 11 falls within an orthographic projection of the light shielding layer 122 on the substrate layer 11. The active layer 14 includes a channel region 141, a source contact region 142 and a drain contact region 143 disposed at two sides of the channel region 141. The active layer 14 is disposed at intervals from the first storage capacitor electrode 144. The light shielding layer 122 is disposed correspondingly to the first storage capacitor electrode 144 to form a first storage capacitor.

In this embodiment, the source contact region 142 and the drain contact region 143 of the active layer 14, and the first storage capacitor electrode 144 are all ion-doped regions, and have conductor characteristics. The channel region 141 is a non-doped region, and has semiconductor characteristics. In an embodiment, a material of the active layer 14 may be oxide semiconductor material, such as indium zinc oxide (IZO), gallium indium oxide (IGO), indium gallium zinc oxide (IGZO), indium gallium tin oxide (IGTO), or indium gallium zinc tin oxide (IGZTO). In another embodiment, a material of the active layer 14 may also be amorphous silicon, monocrystalline silicon, low temperature polysilicon, etc.
Step S15): forming a gate insulating layer 15 on the active layer 14 and the buffer layer 13, referring to FIG. 5. Specifically, a first gate insulating layer 151 is formed on an upper surface of the active layer 14, and a second gate insulating layer 152 is formed on the upper surface of the buffer layer 13 in a same process step. A material of the gate insulating layer 15 may be selected from one or more material including silicon nitride (SiNx), silicon oxide (SiOx) and silicon oxynitride (SiOxNy).
Step S16): forming the second metal layer 16 on the gate insulating layer 15, referring to FIG. 5. Specifically, a metal material is deposited on an upper surface of the gate insulating layer 15 to form the second metal layer 16. The metal material may be metal material such as aluminum (Al), silver (Ag), tungsten (W), copper (Cu), nickel (Ni), chromium (Cr), molybdenum (Mo), titanium (Ti), platinum (Pt), tantalum (Ta), and neodymium (Nd), or alloys or nitrides of the aforesaid metal material. These materials may be used alone or in combination.
Step S17): patterning the second metal layer 16 to form a gate 161 and a second auxiliary electrode 162 disposed in a same layer, referring to FIG. 5. Specifically, the gate 161 is correspondingly disposed on an upper surface of the first gate insulating layer 151, and the second auxiliary electrode 162 is correspondingly disposed on an upper surface of the second gate insulating layer 152. An orthographic projection of the second auxiliary electrode 162 on the substrate layer 11 at least partially overlaps with an orthographic projection of the first auxiliary electrode 121 on the substrate layer 11.
Step S18): forming a dielectric layer 17 on the gate 161 and the second auxiliary electrode 162, referring to FIG. 5. Specifically, the dielectric layer 17 is formed on upper surfaces of the gate 161 and the second auxiliary electrode 162. The dielectric layer 17 covers the gate 161 and the second auxiliary electrode 162, and extends to the upper surface of the buffer layer 13. A material of the dielectric layer 17 may be selected from one or more material including of silicon nitride (SiNx), silicon oxide (SiOx) and silicon oxynitride (SiOxNy).
Step S19): performing two hole-digging treatment on the dielectric layer 17 to form a first conductive hole 71, a second conductive hole 72, a third conductive hole 73, and a fourth conductive hole 74, referring to FIG. 5. Specifically, during a process of a first hole digging treatment, the first conductive hole 71 and the fourth conductive hole 74 are formed. The first conductive hole 71 goes through the dielectric layer 17 and the buffer layer 13, and exposes a surface of a portion of the first auxiliary electrode 121. The fourth conductive hole 74 goes through the dielectric layer 17 and the buffer layer 13, and exposes a surface of a portion of the light shielding layer 122. During a process of a second hole digging treatment, the second conductive hole 72 and the third conductive hole 73 are formed. The second conductive hole 72 goes through the dielectric layer 17, and exposes a surface of a portion of the second auxiliary electrode 162. The third conductive hole 73 goes through the dielectric layer 17, and exposes a surface of a portion of the active layer 14. That is, in a case that the dielectric layer 17 is performed with the two hole digging treatment, deep holes are first formed, namely the first conductive hole 71 and the fourth conductive hole 74; and then shallow holes are formed, namely the second conductive hole 72 and the third conductive hole 73.
Step S110): forming the third metal layer 18 on the dielectric layer 17. Specifically, a metal material is deposited on an upper surface of the dielectric layer 17 to form the third metal layer 18. The metal material fills the first conductive hole 71, the second conductive hole 72, the third conductive hole 73, and the fourth conductive hole 74, respectively, referring to FIG. 6. The metal material may be aluminum (Al), silver (Ag), tungsten (W), copper (Cu), nickel (Ni), chromium (Cr), molybdenum (Mo), titanium (Ti), platinum (Pt), tantalum (Ta), neodymium (Nd), etc., or alloys or nitrides of the aforesaid metal material. These metal materials may be used alone or in combination.
Step S111): patterning the third metal layer 18 to form a source-drain electrode, a third auxiliary electrode 183, and a second storage capacitor electrode 184 disposed in a same layer, referring to FIG. 6. Specifically, the source-drain electrode is disposed on the dielectric layer 17, and is connected to the active layer 14. The third auxiliary electrode 183 is disposed on the dielectric layer 17, and is connected to the first auxiliary electrode 121 and the second auxiliary electrode 162. An orthographic projection of the third auxiliary electrode 183 on the substrate layer 11 at least partially overlaps with an orthographic projection of the first auxiliary electrode 121 on the substrate layer 11. In this embodiment, the source-drain electrode includes a source electrode 181 and a drain electrode 182. The source electrode 181 is connected to one side of the active layer 14, and the drain electrode 182 is connected to another one side of the active layer 14. The source electrode 181 and the drain electrode 182 are connected to the active layer 14 by third conductive holes 73. The drain electrode 182 is connected to the active layer 14 by one third conductive hole 73, and is connected to the light shielding layer 122 by a fourth conductive hole 74, so that an electrical performance of a transistor is improved, and a channel current is more stable. The light shielding layer 122 is disposed correspondingly to the first storage capacitor electrode 144. The first storage capacitor electrode 144 is disposed correspondingly to the second storage capacitor electrode 184 to form a second storage capacitor.
Step S2): forming a protective layer 2 on the third auxiliary electrode 183, and the protective layer 2 extends to the array substrate 1, referring to FIG. 6.

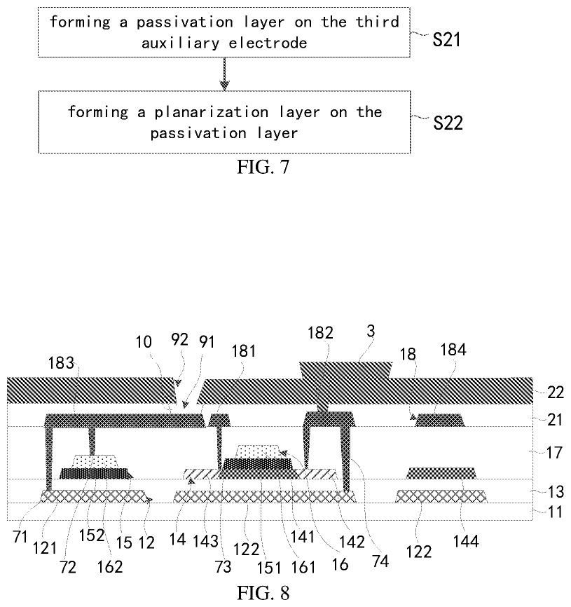

As shown in FIG. 7, steps of forming the protective layer 2 include step S21) to step S22).
Step S21): forming a passivation layer 21 on the third auxiliary electrode 183, referring to FIG. 6. Specifically, the passivation layer 21 is formed on the third auxiliary electrode 183. A material of the passivation layer 21 can be selected from one or more material including silicon nitride (SiNx), silicon oxide (SiOx) and silicon nitride (SiOxNy).
Step S22): forming a planarization layer 22 on the passivation layer 21, referring to FIG. 6. Specifically, the planarization layer 22 is formed on the passivation layer 21. A material of the planarization layer 22 may be selected from one or more material including silicon nitride (SiNx), silicon oxide (SiOx) and silicon oxynitride (SiOxNy).
Step S3): performing a hole digging treatment on the protective layer 2, so that the protective layer 2 is provided with an undercut opening 10, the undercut opening 10 is configured to expose a portion of the third auxiliary electrode 183, referring to FIG. 8.

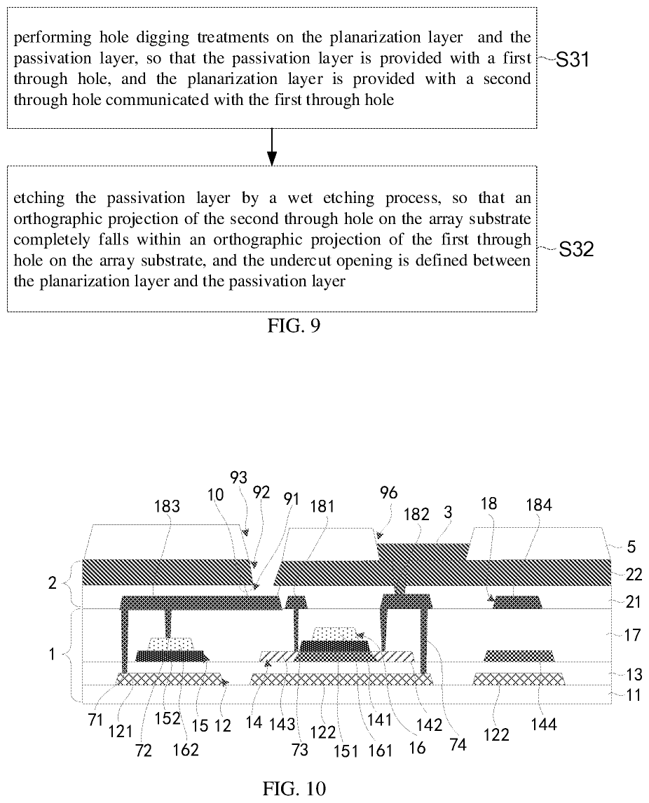

As shown in FIG. 9, steps of performing a hole digging treatment on the protective layer 2 includes step S31) to step S32).
Step S31): performing hole digging treatments on the planarization layer 22 and the passivation layer 21, so that the passivation layer 21 is provided with a first through hole 91, and the planarization layer 22 is provided with a second through hole 92 communicated with the first through hole 91, referring to FIG. 8. Specifically, in a case that the hole digging treatments are performed on the planarization layer 22 and the passivation layer 21, the passivation layer 21 is provided with a fourth through hole 94. The planarization layer 22 is provided with a fifth through hole 95. The fifth through hole 95 is communicated with the fourth through hole 94, so that a surface of the active layer 14 is exposed.
Step S32): etching the passivation layer 21 by a wet etching process, so that an orthographic projection of the second through hole 92 on the array substrate 1 completely falls within an orthographic projection of the first through hole 91 on the array substrate 1, and the undercut opening 10 is defined between the planarization layer 22 and the passivation layer 21, referring to FIG. 8. Specifically, a region in which the undercut opening 10 is disposed is defined by a photolithography process, and then the passivation layer 21 is etched by the wet etching process, so that the undercut opening 10 is defined between the planarization layer 22 and the passivation layer 21. It should be noted that, except for the region in which the undercut opening 10 is disposed, other regions are protected by a photoresist and can not be affected by an etching solution. The undercut opening 10 is configured to expose a portion of the third auxiliary electrode 183. In this embodiment, the diameter of a bottom portion of the second through hole 92 is less than the diameter of a top portion of the first through hole 91, such an arrangement ensure that the undercut opening 10 is defined between the planarization layer 22 and the passivation layer 21. Preferably, the diameter of an orthographic projection of the second through hole 92 on the substrate layer 11 is less than the diameter of an orthographic projection of the first through hole 91 on the substrate layer 11, such an arrangement can further ensure that at least a portion of the planarization layer 22 can extend into the first through hole 91, so that the undercut opening 10 is defined between the planarization layer 22 and the passivation layer 21.
Step S4): forming an anode 3 on the protective layer 2, referring to FIG. 8. Specifically, a transparent conductive metal oxide is deposited on the protective layer 2, and then a yellow light process is carried out to form the anode 3. The transparent conductive metal oxide is completely filled in the fourth through hole 94 and the fifth through hole 95, so that the anode 3 is connected to source electrode 181 after the anode 3 is formed. The transparent conductive metal oxide may be indium tin oxide (ITO, Indium tin oxide).

In other embodiments, the steps S4) and S32) can be exchanged, as long as the undercut opening 10 can be defined between the planarization layer 22 and the passivation layer 21, and the anode 3 is formed on the protective layer 2.
Step S5): forming a pixel defining layer 5 on the protective layer 2. The pixel defining layer 5 is provided with a third through hole 93 and a pixel opening 96. The third through hole 93 is communicated with the second through hole 92, and the pixel opening 96 is configured to expose the anode 3, referring to FIG. 10.
Step S6): forming a light emitting functional layer 4 on the anode 3, as shown in FIG. 1. Specifically, the light emitting functional layer 4 is disposed on the anode 3 and the pixel defining layer 5, and is disconnected at the undercut opening 10. That is, a portion of the light emitting functional layer 4 may be connected to the third auxiliary electrode 183 disposed at the undercut opening 10, and other portions of the light emitting functional layer 4 may not be connected to the third auxiliary electrode 183 disposed at the undercut opening 10. That is, the undercut opening 10 may disconnect some of the film layers thereon. In this embodiment, the light emitting functional layer 4 sequentially includes a hole injection layer 41, a hole transporting layer 42, a light emitting layer 43, an electron transporting layer 44, and an electron injection layer 45 from bottom to top, as shown in FIG. 2.
Step S7): forming a cathode 6 on the light emitting functional layer 4. The cathode 6 extends into the undercut opening 10 and is connected to the third auxiliary electrode 183, as shown in FIG. 1. Specifically, the cathode 6 is disposed on the light emitting functional layer 4. The cathode 6 extends into the undercut opening 10 and is connected to the third auxiliary electrode 183. A pattern of the cathode 6 is the same as that of the light emitting functional layer 4. A material of the cathode 6 may be metal or alloy, such as silver or magnesium-silver alloy. It can be understood that the cathode 6 has a light-transmitting property, so that lights emitted by the light emitting layer 43 can pass through the cathode 6 and be emitted. That is, the OLED display panel provided in this embodiment is a top-emission OLED display panel. Exemplarily, a light transmittance of the cathode 6 is greater than 30%, such as 30%, 40%, 50%, 60%, 70%, 80%, 90%, 95%, or 99%.

As shown in FIG. 2, the third auxiliary electrode 183 is connected to the first auxiliary electrode 121 through the first conductive hole 81, and the third auxiliary electrode 183 is connected to the second auxiliary electrode 162 through the second conductive hole 82. With such arrangements, the third auxiliary electrode 183 is connected to the second auxiliary electrode 162 and the first auxiliary electrode 121 to form a cathode overlapping structure, so that an impedance of the cathode 6 is reduced, thereby improving a display uniformity of the OLED display panel.

An embodiment of the present application further provides a display terminal, the display terminal includes a terminal body and the OLED display panel mentioned above. The terminal body is connected to the OLED display panel.

### Embodiment 2

This embodiment provides an organic light emitting diode (OLED) display panel and a method of manufacturing the same, and a display terminal. This embodiment includes all technical solutions of the embodiment 1, and differences include that, in this embodiment, the second auxiliary electrode 162 is disposed between two first conductive holes 71, and the third auxiliary electrode 183 is connected to the second auxiliary electrode 162 through two second conductive holes 72.

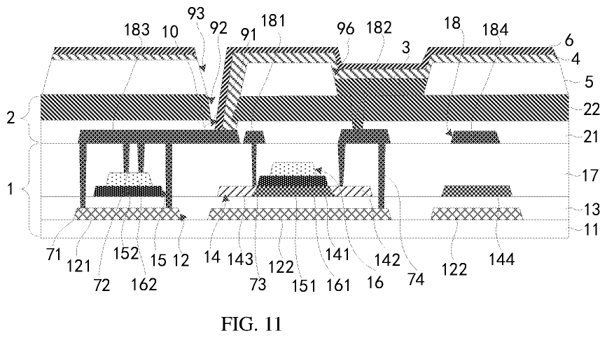

As shown in FIG. 11, the third auxiliary electrode 183 is connected to the first auxiliary electrode 121 through two first conductive holes 71. One of the two first conductive holes 71 is connected to one side of the first auxiliary electrode 21, and another one of the two first conductive holes 71 is connected to another side of the first auxiliary electrode 121. The second auxiliary electrode 162 is disposed between the two first conductive holes 71. The third auxiliary electrode 183 is connected to the second auxiliary electrode 162 by two second conductive holes 72. With such arrangements, the third auxiliary electrode 183 is connected in parallel with the second auxiliary electrode 162 and the first auxiliary electrode 121 to form a cathode overlapping structure. Thus, an impedance of the cathode 6 is further reduced, so that a voltage drop (IR Drop) is reduced, thereby improving a display uniformity of the OLED display panel. In this embodiment, the second auxiliary electrode 162 is disposed between the two first conductive holes 71, such an arrangement can save a space occupied by conductive holes inside the array substrate 1, thereby improving a pixels per inch (PPI). In other embodiments, the two second conductive holes 72 can be disposed on a left side or a right side of the gate insulating layer 15, as long as the third auxiliary electrode 183 can form a parallel circuit with the second auxiliary electrode 162 and the first auxiliary electrode 121.

As shown in FIG. 1 and FIG. 11, the cathode overlapping structure in FIG. 1 is compared with in the cathode overlapping structure FIG. 11. In FIG. 11, the third auxiliary electrode 183 is connected to the first auxiliary electrode 121 through two first conductive holes 71, and is connected to the second auxiliary electrode 162 through two second conductive holes 72. In FIG. 1, the third auxiliary electrode 183 is connected to the first auxiliary electrode 121 through one first conductive holes 71, and is connected to the second auxiliary electrode 162 through one second conductive holes 72. Therefore, the impedance of the cathode overlapping structure in FIG. 11 is less than that of the cathode overlapping structure in FIG. 1, so that the voltage drop is less. That is to say, the cathode overlapping structure in FIG. 11 has a better effect of reducing the impedance of the cathodes 6, which is beneficial to further improve the problem of non-uniform image display.

Therefore, in the OLED display panel provided in this embodiment, the first auxiliary electrode 121, the second auxiliary electrode 162, and the third auxiliary electrode 183 are disposed on the array substrate 1 and are insulated from each other. The third auxiliary electrode 183 is connected to the first auxiliary electrode 121 and the second auxiliary electrode 162 to form the cathode overlapping structure including a parallel connected structure. Furthermore, the protective layer 2 is provided with the undercut opening 10, the undercut opening 10 is configured to expose a portion of the third auxiliary electrode 183. The cathode is connected to the cathode overlapping structure to define a cathode overlapping region, so that the impedance of the cathode 6 is reduced and the voltage drop (IR Drop) is reduced, thereby further improving display uniformity of the OLED display panel.

This embodiment further provides a method of manufacturing an organic light emitting diode (OLED) display panel, this embodiment includes all technical solutions of the method of manufacturing the OLED display panel of embodiment 1, and differences include that, in this embodiment, in a case that hole digging treatments are performed on the dielectric layer 17, two first conductive holes 71 and two second conductive holes 72 are formed. Therefore, the third auxiliary electrode 183 is connected to the first auxiliary electrode 121 through two first conductive holes 71, and the third auxiliary electrode 183 is connected to the second auxiliary electrode 162 by two second conductive holes 72. One of the two first conductive holes 71 is connected to one side of the first auxiliary electrode 21, and another one of the two first conductive holes 71 is connected to another side of the first auxiliary electrode 121. The second auxiliary electrode 162 is disposed between the two first conductive holes 71. Each conductive holes 72 is connected to the second auxiliary electrode 162. With such arrangements, the third auxiliary electrode 183 is connected in parallel with the second auxiliary electrode 162 and the first auxiliary electrode 121 to form a cathode overlapping structure. Thus, an impedance of the cathode 6 is further reduced, so that a voltage drop (IR Drop) is reduced, thereby improving a display uniformity of the OLED display panel. In this embodiment, the second auxiliary electrode 162 is disposed between the two first conductive holes 71, such an arrangement can save a space occupied by conductive holes inside the array substrate 1. In other embodiments, the two second conductive holes 72 can be disposed on a left side or a right side of the gate insulating layer 15, as long as the third auxiliary electrode 183 can form a parallel circuit with the second auxiliary electrode 162 and the first auxiliary electrode 121.

The OLED display panel and the method of manufacturing the same and the display terminal provided in the embodiments of the present application are described in detail above. Specific implementations are used to illustrate principles and implementations of the present application. The descriptions of the above-mentioned embodiments are only used to help understand the technical solutions and core ideas of the present application. Those of ordinary skill in the art should understand that they can still modify the technical solutions described in the foregoing embodiments, or equivalently replace some of the technical features; and these modifications or replacements do not cause the essence of the corresponding technical solutions to deviate from the scope of the technical solutions of the embodiments of the present application.

What is claimed is:

1. An organic light emitting diode (OLED) display panel, comprising:
an array substrate comprising a first auxiliary electrode, a second auxiliary electrode, a third auxiliary electrode, and interlayer insulating layers; wherein the interlayer insulating layers are disposed between the first auxiliary electrode and the second auxiliary electrode, and between the second auxiliary electrode and the third auxiliary electrode; the second auxiliary electrode is disposed on the first auxiliary electrode, and the third auxiliary electrode is disposed on the second auxiliary electrode; and the third auxiliary electrode is connected to the first auxiliary electrode and the second auxiliary electrode;
a protective layer disposed on the third auxiliary electrode and is provided with a undercut opening, wherein the undercut opening is configured to expose a portion of the third auxiliary electrode;
an anode disposed on the protective layer;
a light emitting functional layer disposed on the anode; and
a cathode disposed on the light emitting functional layer, wherein the cathode extends into the undercut opening and is connected to the third auxiliary electrode.

2. The organic light emitting diode display panel of claim 1, wherein the third auxiliary electrode is connected to the first auxiliary electrode by at least one first conductive hole; and the third auxiliary electrode is connected to the second auxiliary electrode by at least one second conductive hole.

3. The organic light emitting diode display panel of claim 2, wherein the third auxiliary electrode is connected to the first auxiliary electrode by two first conductive holes; one of the two first conductive holes is connected to one side of the first auxiliary electrode, and another one of the two first conductive holes is connected to another side of the first auxiliary electrode; and the second auxiliary electrode is disposed between the two first conductive holes.

4. The organic light emitting diode display panel of claim 2, wherein the third auxiliary electrode is connected to the second auxiliary electrode by two second conductive holes.

5. The organic light emitting diode display panel of claim 1, wherein the array substrate further comprises:
a light shielding layer disposed in a same layer as the first auxiliary electrode;
a gate disposed in a same layer as the second auxiliary electrode; and
a source-drain electrode disposed in a same layer as the third auxiliary electrode.

6. The organic light emitting diode display panel of claim 5, further comprising:
a substrate layer, wherein the light shielding layer and the first auxiliary electrode are disposed on the substrate layer;
a buffer layer disposed on the substrate layer and covering the light shielding layer and the first auxiliary electrode;
an active layer disposed on the buffer layer, wherein an orthographic projection of the active layer on the substrate layer falls within an orthographic projection of the light shielding layer on the substrate layer;
a first gate insulating layer correspondingly disposed on the active layer; and
a second gate insulating layer correspondingly disposed on the buffer layer; and
a dielectric layer covering the gate and the second auxiliary electrode, and extending onto the buffer layer;
wherein the gate is correspondingly disposed on the first gate insulating layer, and the second auxiliary electrode is correspondingly disposed on the second gate insulating layer; and an orthographic projection of the second auxiliary electrode on the substrate layer at least partially overlaps with an orthographic projection of the first auxiliary electrode on the substrate layer; and
wherein the source-drain electrode is disposed on the dielectric layer and is connected to the active layer; the third auxiliary electrode is disposed on the dielectric layer and is connected to the first auxiliary electrode and the second auxiliary electrode; an orthographic projection of the third auxiliary electrode on the substrate layer at least partially overlaps with an orthographic projection of the first auxiliary electrode on the substrate layer; and the interlayer insulating layers comprises the buffer layer, the dielectric layer, and the protective layer.

7. The organic light emitting diode display panel of claim 1, wherein the protective layer comprises:
a passivation layer disposed on the third auxiliary electrode and provided with a first through hole; and
a planarization layer disposed on the passivation layer and provided with a second through hole, wherein the second through hole is communicated with the first through hole, and an orthographic projection of the second through hole on the array substrate falls within an orthographic projection of the first through hole on the array substrate, so that the undercut opening is defined between the planarization layer and the passivation layer.

8. The organic light emitting diode display panel of claim 7, further comprising:
a pixel defining layer disposed on the protective layer and provided with a third through hole and a pixel opening, wherein the third through hole is communicated with the second through hole, and the pixel opening is configured to expose the anode;
wherein the light emitting functional layer is disposed on the anode and the pixel defining layer; the cathode is disposed on the light emitting functional layer and extends into the third through hole and the undercut opening, and the cathode is connected to the third auxiliary electrode.

9. A method of manufacturing an organic light emitting diode (OLED) display panel, comprising following steps:
forming an array substrate, the step of forming of the array substrate comprising:
forming a first metal layer;
patterning the first metal layer to form a first auxiliary electrode;
forming a second metal layer on the first metal layer;
patterning the second metal layer to form a second auxiliary electrode;
forming a third metal layer on the second metal layer; and
patterning the third metal layer to form a third auxiliary electrode, wherein interlayer insulating layers are disposed between the first auxiliary electrode and the second auxiliary electrode, and between the second auxiliary electrode and the third auxiliary electrode; and the third auxiliary electrode is connected to the first auxiliary electrode and the second auxiliary electrode;
forming a protective layer disposed on the third auxiliary electrode and extending to the array substrate;
performing a hole-digging treatment on the protective layer, so that the protective layer is provided with an undercut opening exposing a portion of the third auxiliary electrode;
forming an anode disposed on the protective layer;
forming a light emitting functional layer disposed on the anode; and
forming a cathode disposed on the light emitting functional layer, wherein the cathode extends into the undercut opening and is connected to the third auxiliary electrode.

10. The method of manufacturing the organic light emitting diode display panel of claim 9, wherein the step of forming the protective layer comprises:
forming a passivation layer on the third auxiliary electrode; and
forming a planarization layer disposed on the passivation layer;
wherein the step of performing the hole-digging treatment on the protective layer comprises:
performing the hole-digging treatment on the planarization layer and the passivation layer, so that the passivation layer is provided with a first through hole and the planarization layer is provided with a second through hole communicate with the first through hole; and
etching the passivation layer by a wet etching process, so that an orthographic projection of the second through hole on the array substrate falls into an orthographic projection of the first through hole on the array substrate, and the undercut opening is defined between the planarization layer and the passivation layer.

11. The method of manufacturing the organic light emitting diode display panel of claim 9, wherein in the step of patterning the first metal layer to form a first auxiliary electrode, the first metal layer is patterned to form a light shielding layer disposed in a same layer as the first auxiliary electrode;
wherein in the step of patterning the second metal layer to form a second auxiliary electrode, the second metal layer is patterned to form a gate disposed in a same layer as the second auxiliary electrode; and
wherein in the step of patterning the third metal layer to form a third auxiliary electrode, the third metal layer is patterned to form a source-drain electrode disposed in a same layer as the third auxiliary electrode.

12. A display terminal, comprising a terminal body and an organic light emitting diode display panel connected to each other, the organic light emitting diode display panel comprising:
an array substrate comprising a first auxiliary electrode, a second auxiliary electrode, a third auxiliary electrode, and interlayer insulating layers; wherein the interlayer insulating layers are disposed between the first auxiliary electrode and the second auxiliary electrode, and between the second auxiliary electrode and the third auxiliary electrode; the second auxiliary electrode is disposed on the first auxiliary electrode, and the third auxiliary electrode is disposed on the second auxiliary electrode; and the third auxiliary electrode is connected to the first auxiliary electrode and the second auxiliary electrode;
a protective layer disposed on the third auxiliary electrode and is provided with a undercut opening, wherein the undercut opening is configured to expose a portion of the third auxiliary electrode;
an anode disposed on the protective layer;
a light emitting functional layer disposed on the anode; and
a cathode disposed on the light emitting functional layer, wherein the cathode extends into the undercut opening and is connected to the third auxiliary electrode.

13. The display terminal of claim 12, wherein the third auxiliary electrode is connected to the first auxiliary electrode by at least one first conductive hole; and the third auxiliary electrode is connected to the second auxiliary electrode by at least one second conductive hole.

14. The display terminal of claim 13, wherein the third auxiliary electrode is connected to the first auxiliary electrode by two first conductive holes; one of the two first conductive holes is connected to one side of the first auxiliary electrode, and another one of the two first conductive holes is connected to another side of the first auxiliary electrode; and the second auxiliary electrode is disposed between the two first conductive holes.

15. The display terminal of claim 13, wherein the third auxiliary electrode is connected to the second auxiliary electrode by two second conductive holes.

16. The display terminal of claim 12, wherein the array substrate further comprises:
a light shielding layer disposed in a same layer as the first auxiliary electrode;
a gate disposed in a same layer as the second auxiliary electrode; and
a source-drain electrode disposed in a same layer as the third auxiliary electrode.

17. The display terminal of claim 16, wherein the array substrate further comprises:
a substrate layer, wherein the light shielding layer and the first auxiliary electrode are disposed on the substrate layer;
a buffer layer disposed on the substrate layer and covering the light shielding layer and the first auxiliary electrode;
an active layer disposed on the buffer layer, wherein an orthographic projection of the active layer on the substrate layer falls within an orthographic projection of the light shielding layer on the substrate layer;
a first gate insulating layer correspondingly disposed on the active layer;
a second gate insulating layer correspondingly disposed on the buffer layer; and
a dielectric layer covering the gate and the second auxiliary electrode, and extending onto the buffer layer;
wherein the gate is correspondingly disposed on the first gate insulating layer, the second auxiliary electrode is correspondingly disposed on the second gate insulating layer; and an orthographic projection the second auxiliary electrode on the substrate layer at least partially overlaps with an orthographic projection of the first auxiliary electrode on the substrate layer; and
wherein the source-drain electrode is disposed on the dielectric layer and is connected to the active layer; the third auxiliary electrode is disposed on the dielectric layer and is connected to the first auxiliary electrode and the second auxiliary electrode; an orthographic projection of the third auxiliary electrode on the substrate layer at least partially overlaps with an orthographic projection of the first auxiliary electrode on the substrate layer; and the interlayer insulating layers comprises the buffer layer, the dielectric layer, and the protective layer.

18. The display terminal of claim 12, wherein the protective layer comprises:
a passivation layer disposed on the third auxiliary electrode and provided with a first through hole; and
a planarization layer disposed on the passivation layer and provided with a second through hole, wherein the second through hole is communicated with the first through hole, and an orthographic projection of the second through hole on the array substrate falls within an orthographic projection of the first through hole on the array substrate, so that the undercut opening is defined between the planarization layer and the passivation layer.

19. The display terminal of claim 18, wherein the organic light emitting diode display panel further comprising:
a pixel defining layer disposed on the protective layer and provided with a third through hole and a pixel opening, wherein the third through hole is communicated with the second through hole, and the pixel opening is configured to expose the anode;
wherein the light emitting functional layer is disposed on the anode and the pixel defining layer; the cathode is disposed on the light emitting functional layer and extends into the third through hole and the undercut opening, and the cathode is connected to the third auxiliary electrode.
